(19) United States
(12) Patent Application Publication
(10) Pub. No.: US 2024/0316664 A1
(43) Pub. Date: Sep. 26, 2024

(54) WIRE SAW ABNORMALITY DIAGNOSIS DEVICE AND METHOD

(71) Applicant: KOMATSU NTC LTD., Toyama (JP)

(72) Inventors: Reiji Murata, Toyama (JP); Mitsuru Aki, Toyama (JP); Yuri Shimada, Toyama (JP); Tomoyuki Kawatsu, Toyama (JP)

(21) Appl. No.: 18/579,837

(22) PCT Filed: Jul. 27, 2022
(86) PCT No.: PCT/JP2022/029034

§ 371 Date: Jan. 16, 2024

(30) Foreign Application Priority Data
Aug. 3, 2021 (JP) 2021-127332

(51) Int. Cl. B23D 61/18; B23D 59/00

(52) U.S. Cl. CPC B23D 61/185; B23D 59/001

(57) ABSTRACT

A wire saw abnormality diagnosis device and a wire saw abnormality diagnosis method are provided. The abnormality diagnosis device includes: a diagnosis mode executer that executes a first diagnosis mode, a second diagnosis mode, and a third diagnosis mode before the cutting; a data group acquirer that acquires a first data group, a second data group, and a third data group for pluralities of data items indicating operating states of the wire saw; a deviation information calculator that calculates deviation information relating to deviations derived by comparing a first reference data group, a second reference data group, and a third reference data group with the first data group, the second data group, and the third data group for the pluralities of data items; and a determiner that determines presence or absence of an abnormality in the wire saw based on the calculated deviation information.

### TECHNICAL FIELD

The present invention relates to an abnormality diagnosis device and an abnormality diagnosis method for a wire saw.

### BACKGROUND ART

There are wire saws for cutting a workpiece of a semiconductor material, a magnetic material, or the like with a wire (see Patent Literature 1, for example). Such a wire saw cuts a workpiece by running its wire wound around a plurality of processing rollers at predetermined intervals at a high speed and pressing the workpiece against that wire. The wire saw generally includes the plurality of processing rollers, around which the wire is wound, a feed reel which feeds the wire toward the processing rollers, and a take-up reel which takes up the wire sent from the processing rollers.

Before cutting of a workpiece, the device disclosed in Patent Literature 1 measures the tension of the wire and also measures vibration with a vibration sensor attached to a workpiece holder, and determines whether the wire saw is in a normal state or an abnormal state by using these measurements. Then, if determining that the wire saw is in a normal state, the device cuts the workpiece. This prevents a deterioration in the quality of products such as wafers obtained by cutting the workpiece (see paragraphs and in Patent Literature 1).

### CITATION LIST

### Patent Literature

Patent Literature 1: JP6729697B

### SUMMARY OF INVENTION

### Technical Problem

With the device in Patent Literature 1, it is conceivable that the operation of the wire saw in the measurement performed before cutting a workpiece is performed under the same condition as during the subsequent cutting, e.g., the running speed (linear speed) of the wire is constant.

Here, wire saws have a complicated configuration that requires multi-axis synchronous control for the processing rollers, the feed reel, and the take-up reel. During operation at a constant linear speed, the amounts of the wire held on the feed reel and the take-up reel and their effective diameters change in each moment. Moreover, maintenance may involve repair that grinds grooves in the outer peripheral surfaces of the processing rollers. This may change the effective diameters of the processing rollers to smaller diameters. For these reasons, the device in Patent Literature 1 is not considered capable of fully monitoring the operating state before cutting, and has difficulty in performing a precise abnormality diagnosis.

An object of the present invention is to fully monitor the operating state of a wire saw before cutting and perform a precise abnormality diagnosis.

### Solution to Problem

To achieve the above object, the present invention provides an abnormality diagnosis device for a wire saw which performs cutting on a workpiece with a wire. The wire saw includes a plurality of processing rollers, a wire wound around the plurality of processing rollers, a feed reel that feeds the wire toward the processing rollers, and a take-up reel that takes up the wire sent from the processing rollers. The abnormality diagnosis device includes: a diagnosis mode executer that executes a first diagnosis mode, a second diagnosis mode, and a third diagnosis mode before the cutting, the first diagnosis mode being a mode in which the wire saw is caused to operate so as to set the processing rollers at a constant first rotational speed, the second diagnosis mode being a mode in which the wire saw is caused to operate so as to set the feed reel at a constant second rotational speed, and the third diagnosis mode being a mode in which the wire saw is caused to operate so as to set the take-up reel at a constant third rotational speed; a data group acquirer that acquires a first data group, a second data group, and a third data group for pluralities of data items indicating operating states of the wire saw, respectively, the first data group being acquirable in the first diagnosis mode, the second data group being acquirable in the second diagnosis mode, and the third data group being acquirable in the third diagnosis mode; a deviation information calculator that calculates deviation information relating to deviations derived by comparing a first reference data group, a second reference data group, and a third reference data group with the first data group, the second data group, and the third data group for the pluralities of data items, respectively, the first reference data group being acquired in the first diagnosis mode when the wire saw is normal, the second reference data group being acquired in the second diagnosis mode when the wire saw is normal, and the third reference data group being acquired in the third diagnosis mode when the wire saw is normal; and a determiner that determines presence or absence of an abnormality in the wire saw based on the calculated deviation information.

Also, the present invention provides an abnormality diagnosis method for a wire saw which performs cutting on a workpiece with a wire. The abnormality diagnosis method includes the steps of: executing a first diagnosis mode, a second diagnosis mode, and a third diagnosis mode before the cutting, the first diagnosis mode being a mode in which the wire saw is caused to operate so as to set the processing rollers at a constant first rotational speed, the second diagnosis mode being a mode in which the wire saw is caused to operate so as to set the feed reel at a constant second rotational speed, and the third diagnosis mode being a mode in which the wire saw is caused to operate so as to set the take-up reel at a constant third rotational speed; acquiring a first data group, a second data group, and a third data group for pluralities of data items indicating operating states of the wire saw, respectively, the first data group being acquirable in the first diagnosis mode, the second data group being acquirable in the second diagnosis mode, and the third data group being acquirable in the third diagnosis mode; calculating deviation information relating to deviations derived by comparing a first reference data group, a second reference data group, and a third reference data group with the first data group, the second data group, and the third data group for the pluralities of data items, respectively, the first reference data group being acquired in the first diagnosis mode when the wire saw is normal, the second reference data group being acquired in the second diagnosis mode when the wire saw is normal, the third reference data group being acquired in the third diagnosis mode when the wire saw is normal; and determining presence or absence of an abnormality in the wire saw based on the calculated deviation information.

### Advantageous Effects of Invention

According to the present invention, it is possible to fully monitor the operating state of a wire saw before cutting and perform a precise abnormality diagnosis.

### BRIEF DESCRIPTION OF DRAWINGS

FIG. 1 is a diagram showing a schematic configuration of a wire saw to which an abnormality diagnosis device according to an embodiment of the present invention is applied.

FIG. 2 is a schematic block diagram showing a control configuration of the wire saw.

FIG. 3 is a functional block diagram showing an internal configuration of a control device of the wire saw for abnormality diagnosis.

FIG. 4 is a flowchart showing details of an abnormality diagnosis method according to the embodiment.

### DESCRIPTION OF EMBODIMENTS

An embodiment of the present invention will be described in detail with reference to the drawings as appropriate.

Note that common constituent elements and identical constituent elements in drawings are denoted by the same reference sign, and overlapping description thereof is omitted as appropriate. Moreover, members may be schematically shown with different or exaggerated sizes and shapes for convenience of explanation.

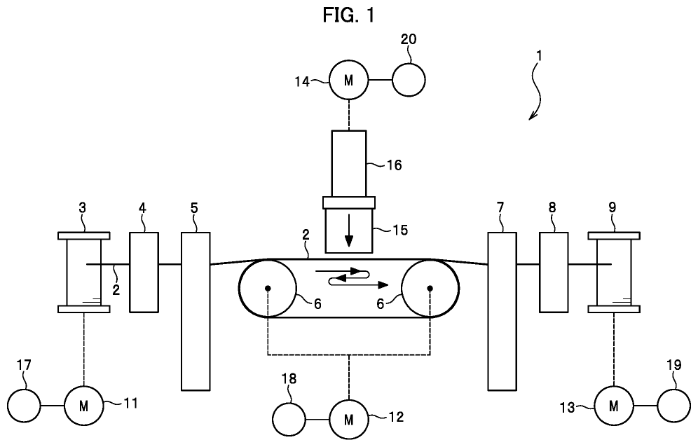

FIG. 1 is a diagram showing a schematic configuration of a wire saw 1 to which an abnormality diagnosis device according to one embodiment of the present invention is applied.

As shown in FIG. 1, the wire saw 1 is for cutting a workpiece 15 with a wire 2. The wire saw 1 includes a plurality of processing rollers 6, a feed reel 3 that feeds the wire 2 toward the processing rollers 6, and a take-up reel 9 that takes up the wire 2 sent from the processing rollers 6. For example, a wire 2 of a fixed abrasive grain type is wound at predetermined intervals around the plurality of processing rollers 6 that extend horizontally and parallelly.

Many annular grooves (not shown) are formed at predetermined pitches in the outer peripheral surfaces of the processing rollers 6, and the wire 2, which is formed of a single piece of a wire material, is continuously wound around each of the grooves in the plurality of processing rollers 6. Two processing rollers 6 are disposed in the present embodiment.

The wire 2 is fed from the feed reel 3, passed through a traverse device 4 and a dancer roller device 5 on the feeding side, wound around the two processing rollers 6 multiple times, passed through a dancer roller device 7 and a traverse device 8 on the winding side, and taken up by the take-up reel 9.

The wire 2 is caused to reciprocate between the two processing rollers 6. In this case, the wire 2 is driven so as to alternately repeat a forward movement by a predetermined amount and a backward movement by a predetermined amount that is a smaller amount of movement than the predetermined amount of the forward movement to thereby move forward in a stepping fashion as a whole. Note that the wire 2 may be driven to move forward continuously in one direction.

The traverse devices 4 and 8 are each provided to make the wire 2 always perpendicular to the axis of the feed reel 3 or the take-up reel 9. The dancer roller devices 5 and 7 are provided to apply a constant tension to the wire 2 while allowing the reciprocation of the wire 2 by means of reciprocating movements of dancer rollers (not shown).

The wire 2 forms a cutting region within a range between the two processing rollers 6 that faces the workpiece 15 to be processed. The intervals of the wire 2 in the cutting region are restricted by the pitches of the grooves formed in the outer peripheral surfaces of the processing rollers 6. The pitches of these grooves determine the thickness of plate-shaped members, i.e., wafers, obtained by cutting the workpiece 15.

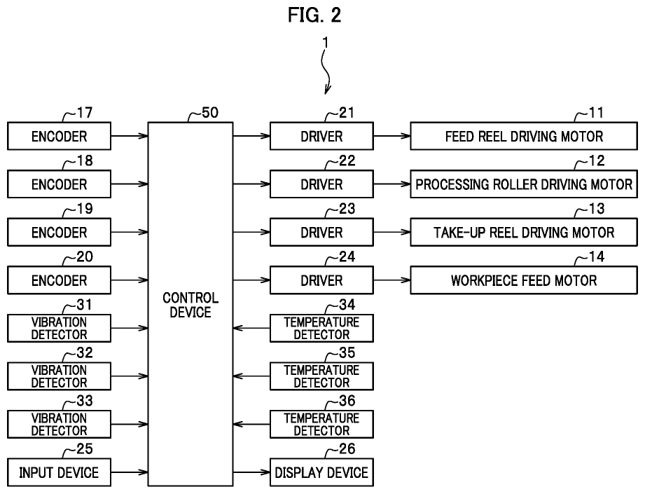

The feed reel 3, the processing rollers 6, and the take-up reel 9 are rotationally driven by a feed reel driving motor 11, a processing roller driving motor 12, and a take-up reel driving motor 13, respectively. These motors 11, 12, and 13 are each controlled by a control device 50 (see FIG. 2).

The workpiece 15 is fixed to a feed device 16 for processing at a position corresponding to the cutting region of the wire 2 between the two processing rollers 6 and is pressed against the cutting region of the wire 2 at a predetermined feed speed. A workpiece feed motor 14 of the feed device 16 incorporates, for example, a mechanism that converts a rotational motion into a linear motion, such as a feed screw unit (not shown). Under control of the control device 50, the workpiece feed motor 14 moves the workpiece 15 in the feed direction for processing at a predetermined feed speed according to the amount of feed of the workpiece 15 in order to cut the workpiece 15. The amount of feed corresponds to the position to which the workpiece 15 is fed or the depth of the cutting, and is detected by means of a signal from an encoder 20 coupled to the workpiece feed motor 14.

Encoders 17, 18, and 19 are coupled to the feed reel driving motor 11, the processing roller driving motor 12, and the take-up reel driving motor 13, respectively. Thus, the rotational speeds of the feed reel 3, the processing rollers 6, and the take-up reel 9 are detected by means of the signals from the encoders 17, 18, and 19, respectively.

FIG. 2 is a schematic block diagram showing a control configuration of the wire saw 1.

As shown in FIG. 2, the wire saw 1 includes the control device 50, which comprehensively controls components of the wire saw 1. The control device 50 includes a CPU (central processing unit) and a RAM, a ROM, and a storage, such as a hard disk drive, none of which is shown in the drawings. The storage stores a program for executing an abnormality diagnosis method according to the present embodiment.

The control device 50 receives the signals from the encoders 17 to 20. The control device 50 controls the driving of the motors 11 to 14 via drivers 21 to 24, respectively. Also, an input device 25 and a display device 26 are connected to the control device 50. The input device 25 receives various information, including accepting the user's operations and the like. The display device 26 displays various information such as an operation screen, a display screen, and a warning message. The control device 50 also receives signals from vibration detectors 31 to 33 and temperature detectors 34 to 36.

The vibration detector 31 detects a vibration characteristic of the feed reel 3 or a support member (not shown) of the feed reel 3. The vibration detector 32 detects the vibration characteristic of the processing rollers 6 or support members (not shown) of the processing rollers 6. The vibration detector 33 detects the vibration characteristic of the take-up reel 9 or a support member (not shown) of the take-up reel 9. The support members of the processing rollers 6, the feed reel 3, and the take-up reel 9 are, for example, bearings, casings in which these bearings are installed, or the like. The temperature detector 34 detects the temperature of the feed reel 3 or the support member of the feed reel 3. The temperature detector 35 detects the temperature of the processing rollers 6 or the support members of the processing rollers 6. The temperature detector 36 detects the temperature of the take-up reel 9 or the support member of the take-up reel 9. The vibration detector 32 and the temperature detector 35 are provided for one or both of the two processing rollers 6.

The bearings of the processing rollers 6 of the wire saw 1, for example, have short lives since they normally rotate at a high speed under a high load. Also, when the processing rollers 6 are rotationally driven, the motor load becomes excessively high in some cases. Also, thermal displacement caused by a temperature rise around the processed regions of the workpiece 15 may cause a deterioration in the processing quality of the workpiece 15, such as warpage of wafers obtained by cutting the workpiece 15. Thus, various abnormalities can occur in the wire saw 1. Here, even if an abnormality is detected during cutting with the wire saw 1, it may be difficult to fix the abnormality, in which case the yield inevitably drops. To address this, in the present embodiment, an abnormality diagnosis is performed on the wire saw 1 before cutting.

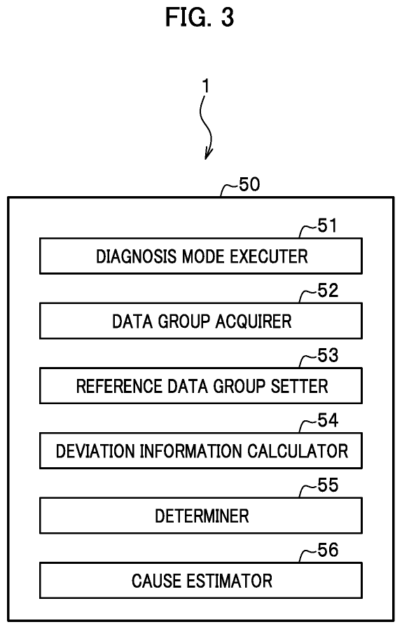

FIG. 3 is a functional block diagram showing an internal configuration of the control device 50 of the wire saw 1 for abnormality diagnosis.

As shown in FIG. 3, the control device 50 of the wire saw 1 includes a diagnosis mode executer 51, a data group acquirer 52, a reference data group setter 53, a deviation information calculator 54, a determiner 55, and a cause estimator 56. The components shown in FIG. 3 form the abnormality diagnosis device of the wire saw 1, and the functions of these components are implemented by executing a predetermined program stored in the storage of the control device 50 on the RAM. Note that the components shown in FIG. 3 may be control circuits formed of hardware.

The diagnosis mode executer 51 executes a first diagnosis mode, a second diagnosis mode, and a third diagnosis mode. The first diagnosis mode is a mode in which the wire saw 1 is caused to operate so as to set the processing rollers 6 at a constant first rotational speed before cutting. The second diagnosis mode is a mode in which the wire saw 1 is caused to operate so as to set the feed reel 3 at a constant second rotational speed before cutting. The third diagnosis mode is a mode in which the wire saw 1 is caused to operate so as to set the take-up reel 9 at a constant third rotational speed. In these first diagnosis mode, second diagnosis mode, and third diagnosis mode, the wire saw 1 is caused to operate with the wire 2 out of contact with the workpiece 15 (hereinafter expressed also as “idle”).

The data group acquirer 52 acquires a first data group acquirable in the first diagnosis mode, a second data group acquirable in the second diagnosis mode, and a third data group acquirable in the third diagnosis mode. The first to third data groups are acquired for pluralities of data items indicating operating states of the wire saw 1, respectively.

In the present embodiment, the plurality of data items for acquiring the first data group is the torque load on the motor 12 rotationally driving the processing rollers 6, the temperature of the processing rollers 6 or the support members (not shown) of the processing rollers 6, and the vibration characteristic of the processing rollers 6 or the support members of the processing rollers 6. Note that other data items may be included. The plurality of data items for acquiring the second data group is the torque load on the motor 11 rotationally driving the feed reel 3, the temperature of the feed reel 3 or the support member (not shown) of the feed reel 3, and the vibration characteristic of the feed reel 3 or the support member of the feed reel 3. Note that other data items may be included. The plurality of data items in the case of acquiring the third data group is the torque load on the motor 13 rotationally driving the take-up reel 9, the temperature of the take-up reel 9 or the support member (not shown) of the take-up reel 9, and the vibration characteristic of the take-up reel 9 or the support member of the take-up reel 9. Note that other data items may be included.

Amplitude, frequency, or characteristic amounts called “amount of variation” and “amount of presence” can be used as the vibration characteristic. The torque loads on the motors 11 to 13 are derived as torque command values to be output to the drivers 21 to 23 from the control device 50 or driving current values to be output to the motors 11 to 13 from the drivers 21 to 23, respectively.

The reference data group setter 53 sets a first reference data group, a second reference data group, and a third reference data group which are data groups forming unit spaces. The first reference data group is acquired in the first diagnosis mode when the wire saw 1 is normal for the same plurality of data items as those acquired for the first data group mentioned above. The second reference data group is acquired in the second diagnosis mode when the wire saw 1 is normal for the same plurality of data items as those acquired for the second data group mentioned above. The third reference data group is acquired in the third diagnosis mode when the wire saw 1 is normal for the same plurality of data items as those acquired for the third data group mentioned above. The first reference data group, the second reference data group, and the third reference data group are set in advance before the first data group, the second data group, and the third data group are acquired.

The deviation information calculator 54 calculates deviation information relating to the deviations derived by comparing the first reference data group, the second reference data group, and the third reference data group with the first data group, the second data group, and the third data group, respectively. Specifically, the deviation information includes first deviation information relating to the deviation between the first reference data group and the first data group, second deviation information relating to the deviation between the second reference data group and the second data group, and third deviation information relating to the deviation between the third reference data group and the third data group. In other words, the deviation information includes first deviation information acquired in the first diagnosis mode, second deviation information acquired in the second diagnosis mode, and third deviation information acquired in the third diagnosis mode.

In the present embodiment, the first deviation information is the Mahalanobis distance between a first unit space formed by the first reference data group and a first signal space formed by the first data group. The second deviation information is the Mahalanobis distance between a second unit space formed by the second reference data group and a second signal space formed by the second data group. The third deviation information is the Mahalanobis distance between a third unit space formed by the third reference data group and a third signal space formed by the third data group. Incidentally, the configuration may be such that the deviation information is calculated by a deviation information calculation model that has been trained by machine learning.

The determiner 55 determines the presence or absence of an abnormality in the wire saw 1 based on the deviation information calculated by the deviation information calculator 54. In the present embodiment, this determination is performed by comparing the Mahalanobis distances being the deviation information with preset threshold values. Specifically, the determiner 55 monitors whether the Mahalanobis distances calculated by the deviation information calculator 54 exceed the Mahalanobis distances calculated by the predetermined threshold values.

When the wire saw 1 is in the normal operating state, the Mahalanobis distances remain within particular ranges. On the other hand, when there is an indication of an abnormal operating state, the correlation between the plurality of data items deviates from the unit space. Thus, it is possible to perform an abnormality diagnosis on the operating state of the wire saw 1 by calculating the Mahalanobis distances, which are used in the MT method and the calibrated error variance method.

If it is determined that an abnormality is present in the wire saw 1, the cause estimator 56 estimates the cause of the abnormality based on the degree of contribution of each of the plurality of data items to the Mahalanobis distance being the deviation information.

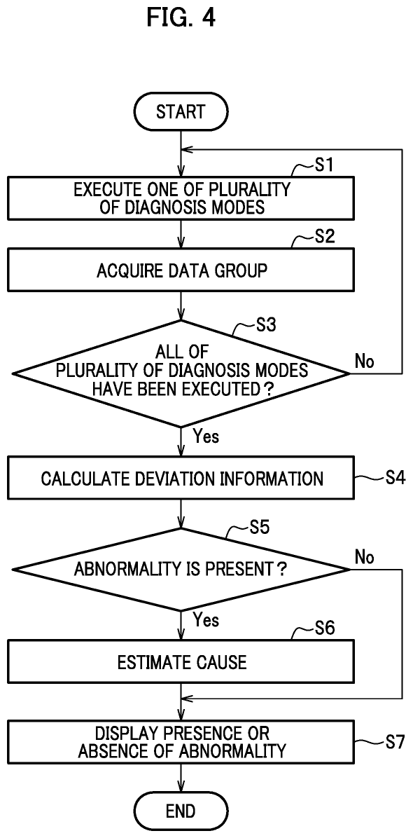

Next, the abnormality diagnosis method according to the present embodiment will be described with reference to FIG. 4.

FIG. 4 is a flowchart showing details of the abnormality diagnosis method according to the present embodiment.

As shown in FIG. 4, the diagnosis mode executer 51 executes one of the plurality of diagnosis modes (step S1). Specifically, first, the diagnosis mode executer 51 executes the first diagnosis mode, in which the wire saw 1 is caused to idle so as to set the processing rollers 6 at the constant first rotational speed, before cutting.

Subsequently, the data group acquirer 52 acquires the first data group acquirable in the first diagnosis mode for the corresponding plurality of data items indicating an operating state of the wire saw 1 (step S2).

In step S3, it is determined whether all of the plurality of diagnosis modes, i.e., all of the first diagnosis mode, the second diagnosis mode, and the third diagnosis mode, have been executed. If all of the plurality of diagnosis modes have been executed (Yes in step S3), the method proceeds to step S4. If there is a diagnosis mode(s) yet to be executed among the plurality of diagnosis modes (No in step S3), the method returns to step S1.

In this way, steps S1 and S2 are iterated, thereby acquiring the second data group acquirable in the second diagnosis mode, in which the wire saw 1 is caused to idle so as to set the feed reel 3 at the constant second rotational speed. Furthermore, the third data group acquirable in the third diagnosis mode, in which the wire saw 1 is caused to idle so as to set the take-up reel 9 at the constant third rotational speed, is acquired.

Subsequently, the deviation information calculator 54 calculates deviation information (step S4). The deviation information is information relating to the deviations derived by comparing the first reference data group, the second reference data group, and the third reference data group with the first data group, the second data group, and the third data group, respectively. Here, the first to third reference data groups are acquired in advance in the first to third diagnosis modes when the wire saw 1 is normal for the pluralities of data items mentioned above.

In step S5, the determiner 55 determines the presence or absence of an abnormality in the wire saw 1 based on the deviation information calculated by the deviation information calculator 54. In the present embodiment, it is determined that no abnormality is present in the wire saw 1 if a Mahalanobis distance being the deviation information does not exceed a preset threshold value. Note that this determination is performed individually for each of the first deviation information, the second deviation information, and the third deviation information forming the deviation information.

If it is determined that no abnormality is present in the wire saw 1 (No in step S5), the method proceeds to step S7. If it is determined that an abnormality is present in the wire saw 1 (Yes in step S5), the method proceeds to step S6.

In step S6, the cause estimator 56 estimates the cause of the abnormality based on the degree of contribution of each of the plurality of data items to the Mahalanobis distance being the deviation information. For example, the cause estimator 56 assumes a data item that contributes to increasing the Mahalanobis distance to a great degree as a cause to be considered. Also, a more specific cause may be estimated, for example, experimentally or empirically from the distribution of the degrees of contribution of the plurality of data items.

In step S7, the result of the determination by the determiner 55, i.e., the presence or absence of an abnormality in the wire saw 1, is displayed on the display device 26. Also, if it has been determined that an abnormality is present in the wire saw 1, the cause of the abnormality estimated by the cause estimator 56 is displayed on the display device 26. At this time, various information such, for example, as a warning message prompting to stop the operation of the wire saw 1 and an experimentally or empirically derived measure may be displayed on the display device 26.

As described above, the abnormality diagnosis device of the wire saw 1 according to the present embodiment includes: the diagnosis mode executer 51, which executes the first diagnosis mode, in which the wire saw 1 is caused to operate so as to set the processing rollers 6 at the constant first rotational speed, the second diagnosis mode, in which the wire saw 1 is caused to operate so as to set the feed reel 3 at the constant second rotational speed, and the third diagnosis mode, in which the wire saw 1 is caused to operate so as to set the take-up reel 9 at the constant third rotational speed, before cutting; the data group acquirer 52, which acquires the first data group acquirable in the first diagnosis mode, the second data group acquirable in the second diagnosis mode, and the third data group acquirable in the third diagnosis mode for the pluralities of data items indicating operating states of the wire saw 1, respectively; the deviation information calculator 54, which calculates deviation information relating to deviations derived by comparing the first reference data group acquired in the first diagnosis mode when the wire saw 1 is normal, the second reference data group acquired in the second diagnosis mode when the wire saw 1 is normal, the third reference data group acquired in the third diagnosis mode when the wire saw 1 is normal, with the first data group, the second data group, and the third data group for the pluralities of data items, respectively; and the determiner 55, which determines the presence or absence of an abnormality in the wire saw 1 based on the calculated deviation information.

In the present embodiment as above, cutting with the wire saw 1 is preceded by execution of the first diagnosis mode, in which the processing rollers 6 rotate at a constant speed, the second diagnosis mode, in which the feed reel 3 rotates at a constant speed, and the third diagnosis mode, in which the take-up reel 9 rotates at a constant speed. Then, in the first to third diagnosis modes, the first to third data groups are acquired for pluralities of data items, respectively, and these are compared with the first to third reference data groups acquired in the normal state, respectively, to calculate deviation information, based on which the presence or absence of an abnormality in the wire saw 1 is determined.

The wire saw 1 is generally caused to operate at a constant linear speed. During such operation, the amounts of the wire held on the feed reel 3 and the take-up reel 9 and their effective diameters change in each moment. Moreover, maintenance may change the effective diameters of the processing rollers 6 to smaller diameters. Thus, the operating state before cutting usually varies, making it difficult to fully monitor the operating state with the conventional technique. On the other hand, in the present embodiment, the first to third diagnosis modes, in which the rotational speeds of the processing rollers 6, the feed reel 3, and the take-up reel 9 are set at individual constant speeds, respectively, are sequentially executed to acquire data groups before cutting.

Thus, according to the present embodiment, it is possible to fully monitor the operating state of the wire saw 1 before cutting and perform a precise abnormality diagnosis. This makes it possible to prevent an abnormality from occurring in the wire saw 1 during cutting. Accordingly, the wire saw 1 will not stop or require repair during the cutting, which improves yield.

In the present embodiment, the plurality of data items for acquiring the first data group and the first reference data group include the torque load on the motor 12 rotationally driving the processing rollers 6, the temperature of the processing rollers 6 or the support members of the processing rollers 6, and the vibration characteristic of the processing rollers 6 or the support members of the processing rollers 6. With this configuration, data groups on data items relating to the processing rollers 6, which are particularly relevant to the abnormality diagnosis of the wire saw 1, are acquired. This makes it possible to efficiently perform an effective abnormality diagnosis.

Also, in the present embodiment, the plurality of data items for acquiring the second data group and the second reference data group include the torque load on the motor 11 rotationally driving the feed reel 3, the temperature of the feed reel 3 or the support member of the feed reel 3, and the vibration characteristic of the feed reel 3 or the support member of the feed reel 3. With this configuration, data groups on data items relating to the feed reel 3, which is relevant to the abnormality diagnosis of the wire saw 1, are acquired. This makes it possible to efficiently perform an effective abnormality diagnosis.

Also, in the present embodiment, the plurality of data items for acquiring the third data group and the third reference data group include the torque load on the motor 13 rotationally driving the take-up reel 9, the temperature of the take-up reel 9 or the support member of the take-up reel 9, and the vibration characteristic of the take-up reel 9 or the support member of the take-up reel 9. With this configuration, data groups on data items relating to the take-up reel 9, which is relevant to the abnormality diagnosis of the wire saw 1, are acquired. This makes it possible to efficiently perform an effective abnormality diagnosis.

Also, in the present embodiment, the deviation information calculator 54 calculates the Mahalanobis distances between unit spaces formed by the preset reference data groups and signal spaces formed by the acquired data groups as deviation information. With this configuration, the presence or absence of an abnormality in the wire saw 1 can be determined based on whether any of the Mahalanobis distances exceeds a predetermined threshold value.

Also, in the present embodiment, the cause estimator 56 is included, which estimates the cause of an abnormality based on the degree of contribution of each of the plurality of data items to the deviation information. With this configuration, it is possible to take an appropriate measure, such as replacement, repair, or adjustment, on a part relating to the estimated caused of the abnormality in the wire saw 1.

Although the present invention has been described based on one embodiment, the present invention is not limited to the configurations described in the embodiment. It is possible to change the configurations described in the embodiment as appropriate without departing from the gist of the present invention, which includes appropriately combining or selecting the configurations. It is also possible to add, remove, and/or replace parts of the configuration in the embodiment.

For example, while two processing rollers 6 are disposed in the embodiment described above, the configuration is not limited to this. For example, three processing rollers 6 may be disposed at the positions of the vertices of an inverted triangle, or four processing rollers 6 may be disposed at the positions of the vertices of a quadrangle.

### REFERENCE SIGNS LIST

1 wire saw
2 wire
3 feed reel
6 processing roller
9 take-up reel
11 to 13 motor
15 workpiece
31 to 33 vibration detector
34 to 36 temperature detector
51 diagnosis mode executer
52 data group acquirer
54 deviation information calculator
55 determiner
56 cause estimator

1. An abnormality diagnosis device for a wire saw which includes a plurality of processing rollers, a wire wound around the plurality of processing rollers, a feed reel that feeds the wire toward the processing rollers, and a take-up reel that takes up the wire sent from the processing rollers, and which performs cutting on a workpiece with the wire, the abnormality diagnosis device comprising:
a diagnosis mode executer that executes a first diagnosis mode, a second diagnosis mode, and a third diagnosis mode before the cutting, the first diagnosis mode being a mode in which the wire saw is caused to operate so as to set the processing rollers at a constant first rotational speed, the second diagnosis mode being a mode in which the wire saw is caused to operate so as to set the feed reel at a constant second rotational speed, and the third diagnosis mode being a mode in which the wire saw is caused to operate so as to set the take-up reel at a constant third rotational speed;
a data group acquirer that acquires a first data group, a second data group, and a third data group for pluralities of data items indicating operating states of the wire saw, respectively, the first data group being acquirable in the first diagnosis mode, the second data group being acquirable in the second diagnosis mode, and the third data group being acquirable in the third diagnosis mode;
a deviation information calculator that calculates deviation information relating to deviations derived by comparing a first reference data group, a second reference data group, and a third reference data group with the first data group, the second data group, and the third data group for the pluralities of data items, respectively, the first reference data group being acquired in the first diagnosis mode when the wire saw is normal, the second reference data group being acquired in the second diagnosis mode when the wire saw is normal, and the third reference data group being acquired in the third diagnosis mode when the wire saw is normal; and
a determiner that determines presence or absence of an abnormality in the wire saw based on the calculated deviation information.

2. The abnormality diagnosis device for a wire saw according to claim 1, wherein a plurality of data items for acquiring the first data group and the first reference data group includes a torque load on a motor rotationally driving the processing rollers, temperature of the processing rollers or a support member of the processing rollers, and a vibration characteristic of the processing rollers or the support member of the processing rollers.

3. The abnormality diagnosis device for a wire saw according to claim 1, wherein a plurality of data items for acquiring the second data group and the second reference data group includes a torque load on a motor rotationally driving the feed reel, temperature of the feed reel or a support member of the feed reel, and a vibration characteristic of the feed reel or the support member of the feed reel.

4. The abnormality diagnosis device for a wire saw according to claim 1, wherein a plurality of data items for acquiring the third data group and the third reference data group includes a torque load on a motor rotationally driving the take-up reel, temperature of the take-up reel or a support member of the take-up reel, and a vibration characteristic of the take-up reel or the support member of the take-up reel.

5. The abnormality diagnosis device for a wire saw according to claim 1, wherein the deviation information calculator calculates Mahalanobis distances by comparing a first unit space, a second unit space, and a third unit space with a first signal space, a second signal space, and a third signal space, respectively, as the deviation information, the first unit space being formed by the first reference data group, the second unit space being formed by the second reference data group, the third unit space being formed by the third reference data group, the first signal space being formed by the first data group, the second signal space being formed by the second data group, and the third signal space being formed by the third data group.

6. The abnormality diagnosis device for a wire saw according to claim 1, further comprising a cause estimator that, if it is determined that an abnormality is present in the wire saw, estimates a cause of the abnormality based on a degree of contribution of the plurality of data items to the deviation information.

7. An abnormality diagnosis method for a wire saw which includes a plurality of processing rollers, a wire wound around the plurality of processing rollers, a feed reel that feeds the wire toward the processing rollers, and a take-up reel that takes up the wire sent from the processing rollers, and which performs cutting on a workpiece with the wire, the abnormality diagnosis method comprising the steps of:
executing a first diagnosis mode, a second diagnosis mode, and a third diagnosis mode before the cutting, the first diagnosis mode being a mode in which the wire saw is caused to operate so as to set the processing rollers at a constant first rotational speed, the second diagnosis mode being a mode in which the wire saw is caused to operate so as to set the feed reel at a constant second rotational speed, and the third diagnosis mode being a mode in which the wire saw is caused to operate so as to set the take-up reel at a constant third rotational speed;
acquiring a first data group, a second data group, and a third data group for pluralities of data items indicating operating states of the wire saw, respectively, the first data group being acquirable in the first diagnosis mode, the second data group being acquirable in the second diagnosis mode, and the third data group being acquirable in the third diagnosis mode;
calculating deviation information relating to deviations derived by comparing a first reference data group, a second reference data group, and a third reference data group with the first data group, the second data group, and the third data group for the pluralities of data items, respectively, the first reference data group being acquired in the first diagnosis mode when the wire saw is normal, the second reference data group being acquired in the second diagnosis mode when the wire saw is normal, and the third reference data group being acquired in the third diagnosis mode when the wire saw is normal; and
determining presence or absence of an abnormality in the wire saw based on the calculated deviation information.
